(19) United States
(12) Patent Application Publication
(10) Pub. No.: US 2002/0102500 A1
(43) Pub. Date: Aug. 1, 2002

(54) Method for raising etching selectivity of oxide to photoresist

(76) Inventors: Lian-Fa Hung, Tainan City (TW); Chan-Lon Yang, Taipei City (TW)

Correspondence Address: Powell, Goldstein, Frazer & Murphy, LLP, 1001 Pennsylvanic Avenue, Suite 600, Washington, DC, 20004, US

(21) Appl. No.: 09/774,485

(22) Filed: Jan. 31, 2001

(51) Int. Cl. G03F 7/00

(52) U.S. Cl. 430/322; 430/323; 430/324

(57) ABSTRACT

In the present invention, a method for raising etching selectivity of an insulating material to a photoresist comprises providing an insulating layer. A photoresist layer is formed on the insulating layer and the photoresist layer has a contact pattern. Next, a protecting layer is formed on surface of the photoresist layer and sidewalls of the contact pattern. Then the partial the insulating layer is removed by using the protecting layer and the photoresist layer as an etching mask. The polymer layer is deposited in gases mixture surrounding of Ar, CH₃F, and C₄F₈. As a key structure of the present invention, the protecting layer can improve the etching selectivity of the insulating layer to photoresist.

### BACKGROUND OF THE INVENTION

1. Field of the Invention

The invention relates to a method for raising etching selectivity of insulating material to photoresist, and more particularly to a method for forming a protecting layer on a photoresist layer and an oxide layer, whereby improves selectivity of the oxide layer to the photoresist layer.

2. Description of the Prior Art

Etching in microelectronic fabrication is a process by which material is removed from silicon substrate or form thin films on the substrate. When a mask layer is used to protect specific regions of the wafer surface, the goal of etching is to precisely remove the material which is not covered by the mask. In general an ideal etch process is not completely attainable. We assume that the mask was not attacked by the etchant, and don't consider that the layers under the etched film can also be attacked by the etchant. In fact, both mask material and underlying layer materials are generally etchable, and these effects may play a significant role in specifying etch process. Note that the underlying material subject to etchant attack may be either the silicon wafer itself, or a film grown or deposited during a previous fabrication step. The ratio of etch rates of different materials is known as the selectivity of an etched process. Thus both: 1) the selectivity with respect to the mask material; and 2) the selectivity with respect to the substrate materials are important characteristics of an etch process.

In general, the selectivity with respect to the mask material, Sfm, plays a role in determining the etched feature sizes. The selectivity with respect to substrate, Sfs, can impact performance and yield. The required selectivity with respect to the mask, Sfm is dependent on several factors including: a) film thickness uniformity; b) film etch rate uniformity; c) mask etch rate uniformity; d) the edge profile of the mask; e) the anisotropy etch rate of the mask; and f) the maximum acceptable loss of line width of the patterns being etched. For many wet-etch process, both Sfm and Sfs are very high, and thus neither the mask or substrate material are affected very much during such well-controlled wet-etch procedures.

However, for dry-etch processes, these desirable circumstances are rarely encountered. Thus, it is necessary to calculate the selectivities that an etching application will require, so that dry-etch processes which are able to meet such specifications can be selected or developed.

### SUMMARY OF THE INVENTION

It is an object of the present invention to provide a method for raising etching selectivity of insulating material to photoresist. A protecting layer formed on the insulating layer and photoresist layer can improve the etching selectivity.

It is another object of the present invention to provide a method for raising etching selectivity of oxide to photoresist by forming a protecting layer on the oxide layer and the photoresist layer. The protecting layer can prevent the photoresist layer against ion bombardment and radical attack during etching oxide step.

In the present invention, a method for raising etching selectivity of an insulating material to a photoresist comprises providing an insulating layer. A photoresist layer is formed on the insulating layer and the photoresist layer has a contact pattern. Next, a protecting layer is formed on surface of the photoresist layer and sidewalls of the contact pattern. Then the partial the insulating layer is removed by using the protecting layer and the photoresist layer as an etching mask. The polymer layer is deposited in gases mixture surrounding of Ar, CH₃F, and C₄F₈. As a key structure of the present invention, the protecting layer can improve the etching selectivity of the insulating layer.

### BRIEF DESCRIPTION OF THE DRAWINGS

A better understanding of the invention may be derived by reading the following detailed description with reference to the accompanying drawing wherein:

FIGS. 1A-1C are a series of cross-sectional schematically diagrams illustrating a method for forming a protecting layer in accordance with the present invention.

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered and that species and types of substrate and dopant as well as other materials substitutions can be freely made without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, a method for raising etching selectivity of oxide material to a photoresist comprises providing a silicon oxide layer. A photoresist layer is formed on the silicon oxide layer and the photoresist layer has a contact pattern. Next, a polymer layer is formed on surface of the photoresist layer and sidewalls of the contact pattern. Then the partial the silicon oxide layer is etched by using the polymer layer and the photoresist layer as an etching mask, whereby a contact is formed in the silicon oxide layer. The polymer layer is deposited in gases mixture surrounding of Ar, CH₃F, and C₄F₈.

For advanced 193 nm photo resist, the primary challenge may come from the high resist thickness loss in the pattern transfer step. Traditional process tuning is hard to keep high photo resist selectivity to meet contact etch requirement.

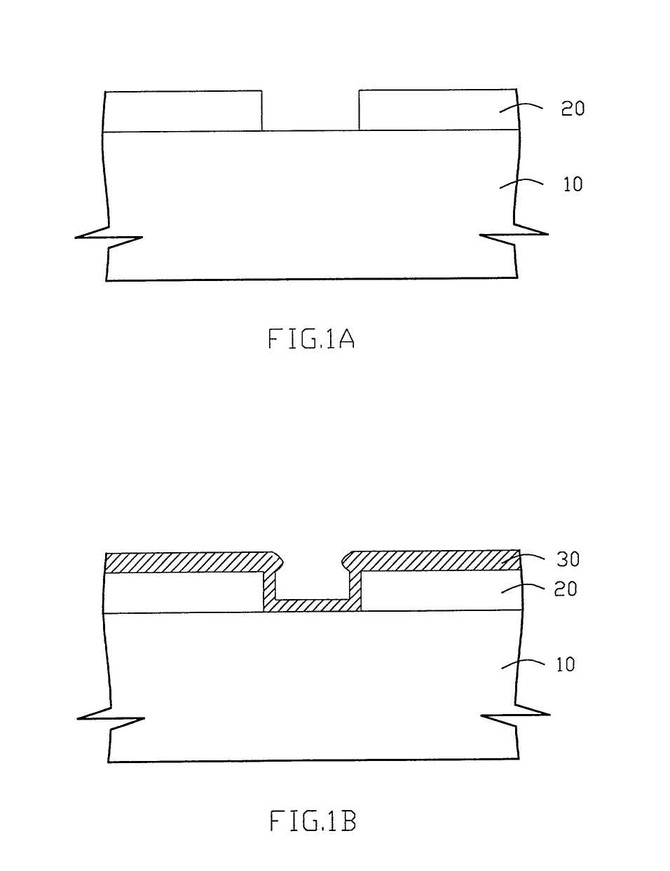

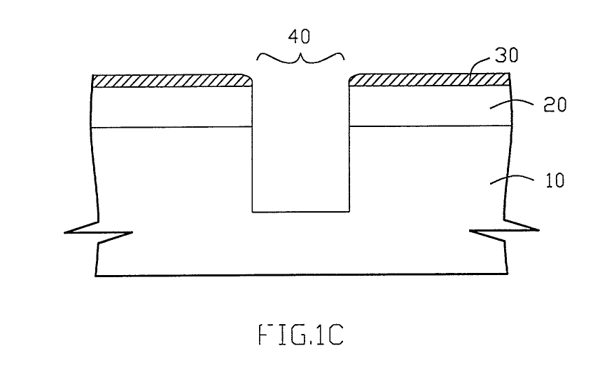

As shown in FIG. 1A, an insulating layer 10 is provided and a patterned mask layer 20 formed thereon. The insulating layer 10, such as silicon oxide layer, is deposited by using chemical vapor deposition at a temperature between about 400° C. to 600° C. and to a thickness between about 3000 to 6000 angstroms.

Next, as shown in FIG. 1B, a protecting layer 30 is conformal deposited on the mask layer and the insulating layer that is exposed by the patterned mask layer. In the preferred embodiment, the protecting layer 30 is deposited in gases mixture surrounding of Ar, CH₃F, and C₄F₈. Furthermore, the deposition of the protecting layer is operated at a power between about 250 Watt to 500 Watt, a pressure between about 50 mTorr to 70 mTorr, and a temperature between 0° C. to 15° C. On the other hand, the Ar flow is between about 150 sccm to 250 sccm, the CH₃F flow between about 10 sccm to 20 sccm and the C₄F₈ flow between about 10 sccm to 20 sccm. Furthermore, the protecting layer 30 on the top surface of the mask layer 20 has a thickness about 1000 angstroms, while on the sidewalls of the mask layer 20 and on the surface of the insulating layer 10 has a thickness about 300 angstroms, individually.

Next, a contact 40 is formed by anisotropy etching the protecting layer 30 and the insulating layer 10 shown in FIG. 1C. In the existence of the protecting layer 30 during anisotropy etching process, the thin mask layer 20 can be protected against etchant radical attack and ion bombardment. On the other hand, compared with the existence of the only mask layer 20, the addition of the protecting layer 30 on the mask layer 20 improves the etching selectivity of the insulating layer to the mask layer. It is observed that the etching selectivity of oxide layer to photoresist layer is 3, while the addition of the protecting layer may raise the etching selectivity to 6.

The object of the present invention is to provide a dump layer, such as the protecting layer in the preferred embodiment, to keep high etching selectivity even though the thickness of the photoresist layer needs to be decreased under consideration to lithography resolution.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for raising etching selectivity of insulating material to photoresist, said method comprising:
providing an insulating layer;
forming a photoresist layer on said insulating layer, said photoresist layer having a contact pattern;
forming a protecting layer on surface of said photoresist layer and at sidewalls of said contact pattern; and
removing partial said insulating by using said protecting layer and said photoresist layer as an etching mask.

2. The method according to claim 1, wherein said removing step is implemented by anisotropy dry etching.

3. The method according to claim 1, wherein said insulating layer comprises a silicon oxide layer.

4. The method according to claim 1, wherein said insulating layer comprises a silicon oxide layer and a plurality of dopants therein.

5. The method according to claim 1, wherein said insulating layer is formed by using chemical vapor deposition.

6. The method according to claim 1, wherein said protecting layer is deposited in gases mixture surrounding of Ar, CH₃F, and C₄F₈.

7. The method according to claim 6, wherein said depositing step is operated at CH₃F flow between about 10 sccm to 20 sccm.

8. The method according to claim 6, wherein said depositing step is operated at C₄F₈ flow between about 10 sccm to 20 sccm.

9. The method according to claim 6, wherein said depositing step is operated at Ar flow between about 150 sccm to 250 sccm.

10. The method according to claim 1, wherein said protecting layer is formed at a temperature between about 0° C. to 15° C.

11. The method according to claim 1, wherein said protecting layer is formed at a pressure between about 50 mTorr to 70 mTorr.

12. The method according to claim 1, wherein said protecting layer is formed at a power between about 250 Watt to 500 Watt.

13. A method for raising etching selectivity of an oxide material to a photoresist, said method comprising:
providing a silicon oxide layer;
forming a photoresist layer on said silicon oxide layer, said photoresist layer having a contact pattern;
forming a polymer layer on surface of said photoresist layer and a plurality of sidewalls of said contact pattern; and
removing partial said silicon oxide layer by using said polymer layer and said photoresist layer as an etching mask, whereby forming a contact in said silicon oxide layer.

14. The method according to claim 13, wherein said polymer layer is deposited in gases mixture surrounding of Ar, CH₃F, and C₄F₈.

15. The method according to claim 14, wherein said polymer layer is deposited at CH₃F flow between about 10 sccm to 20 sccm.

16. The method according to claim 14, wherein said polymer layer is deposited at C₄F₈ flow between about 10 sccm to 20 sccm.

17. The method according to claim 14, wherein said polymer layer is deposited at Ar flow between about 150 sccm to 250 sccm.

18. The method according to claim 13, wherein said polymer layer is deposited at a temperature between about 0° C. to 15° C., a pressure between about 50 mTorr to 70 mTorr and a power between about 250 Watt to 500 Watt.

19. The method according to claim 13, wherein said polymer layer has a thickness on said photoresist layer about 1000 angstroms, on said sidewalls of said contact pattern about 300 angstroms, and on said silicon oxide layer about 300 angstroms.
